(19) United States
(12) Patent Application Publication
(10) Pub. No.: US 2019/0312114 A1
(43) Pub. Date: Oct. 10, 2019

(54) Semiconductor Device with Trench Structure and Production Method

(71) Applicant: Infineon Technologies AG, Neubiberg (DE)

(72) Inventors: Andreas Meiser, Sauerlach (DE); Ralf Rudolf, Dresden (DE)

(21) Appl. No.: 16/376,266

(22) Filed: Apr. 5, 2019

(30) Foreign Application Priority Data
Apr. 6, 2018 (DE) 102018108178.2

(51) Int. Cl. H01L 29/40; H01L 29/06; H01L 21/265; H01L 21/761; H01L 21/765

(52) U.S. Cl. CPC H01L 29/407; H01L 29/063; H01L 21/765; H01L 21/26586; H01L 21/761; H01L 21/2652

(57) ABSTRACT

A semiconductor device includes a semiconductor substrate of a first conductivity type and a semiconductor layer of a second conductivity type on the semiconductor substrate, such that a first section of a pn junction is formed between the semiconductor layer and the semiconductor substrate. A trench structure extends through the semiconductor layer into the semiconductor substrate. The trench structure includes an insulation structure and a contact structure. The insulation structure is formed between the semiconductor layer and the contact structure. The contact structure is electrically connected to the semiconductor substrate at a bottom of the trench. A first semiconductor region of the second conductivity type adjoins the insulation structure and extends along the trench structure into a depth range between the first section of the pn junction and the bottom, such that a second section of the pn junction is formed between the first semiconductor region and the semiconductor substrate.

### TECHNICAL FIELD

This application relates to semiconductor devices with a trench structure and to a production method therefor.

### BACKGROUND

Power semiconductors are used for example in applications which are specified for increasingly greater power consumptions, e.g. power driver circuits for applications in automotive and industrial electronics. This is associated with requirements in respect of an improved voltage blocking capability of the semiconductor devices in order for example to cope with increased voltages in the on-board electrical system of motor vehicles. This application is devoted to improving the voltage blocking capability of semiconductor devices and to methods for producing same.

### SUMMARY

The present disclosure relates to a semiconductor device comprising a semiconductor substrate of a first conductivity type and a semiconductor layer of a second conductivity type on the semiconductor substrate, such that a first section of a pn junction is formed between the semiconductor layer and the semiconductor substrate. A trench structure extends through the semiconductor layer into the semiconductor substrate. The trench structure comprises an insulation structure and a contact structure. The insulation structure is formed between the semiconductor layer and the contact structure and also between the semiconductor substrate and the contact structure. The contact structure is electrically connected to the semiconductor substrate at a bottom of the trench structure. A first semiconductor region of the second conductivity type adjoins the insulation structure and extends along the trench structure into a depth range between the first section of the pn junction and the bottom, such that a second section of the pn junction is formed between the first semiconductor region and the semiconductor substrate.

The present disclosure additionally relates to a method for producing a semiconductor device. The method comprises forming a semiconductor layer of a second conductivity type on a semiconductor substrate of a first conductivity type. The method additionally comprises forming a trench extending through the semiconductor layer into the semiconductor substrate. The method also comprises forming a first semiconductor region of the second conductivity type at a sidewall of the trench by introducing a dopant through the sidewall into the semiconductor substrate and into the semiconductor layer, and forming an insulation structure and a contact structure in the trench, wherein the insulation structure is formed between the semiconductor layer and the contact structure and also between the semiconductor substrate and the contact structure, and the contact structure is electrically connected to the semiconductor substrate at a bottom of the trench.

Further features and advantages of the disclosed subject matter will become apparent to the person skilled in the art from the following detailed description and from the drawings.

### BRIEF DESCRIPTION OF THE DRAWINGS

The accompanying drawings convey a deeper understanding of the invention, are included in the disclosure and form part thereof. The drawings illustrate embodiments of the present invention and together with the description set out the principles of the invention. Further embodiments of the invention and intended advantages are evident from the understanding of the following detailed description.

FIG. 1 shows one exemplary embodiment of a semiconductor device with a trench structure in a schematic cross-sectional view.

FIGS. 2A and 2B illustrate electrical potential lines during off-state operation of semiconductor devices.

FIGS. 3A and 3B show exemplary embodiments of the semiconductor device from FIG. 1 with differently configured semiconductor regions adjoining the trench structure.

FIG. 4 shows one exemplary embodiment of the semiconductor device from FIG. 1 with a semiconductor layer on a semiconductor substrate, wherein the semiconductor layer comprises a plurality of areas of different dopant concentrations.

FIG. 5 shows one exemplary embodiment of the semiconductor device from FIG. 1 with a semiconductor connection region at a surface of the semiconductor layer.

FIG. 6 shows a flow diagram for illustrating a method for producing a semiconductor device.

FIGS. 7A to 7C are schematic cross-sectional views for illustrating a method for producing the semiconductor layer in the exemplary embodiment from FIG. 4.

FIGS. 8A and 8B show a schematic cross-sectional view and a plan view of the semiconductor substrate for illustrating process parameters during the production of the semiconductor device.

### DETAILED DESCRIPTION

In the following detailed description, reference is made to the accompanying drawings, which form part of the disclosure and show specific exemplary embodiments of a semiconductor device and of a method for producing a semiconductor device for illustration purposes. It goes without saying that further exemplary embodiments exist. It likewise goes without saying that structural and/or logical changes can be made to the exemplary embodiments, without departing in the process from what is defined by the patent claims. The description of the exemplary embodiments is non-limiting in this respect. In particular, features of exemplary embodiments described below can be combined with features of other exemplary embodiments from among those described, unless something different is evident from the context.

The terms “have”, “contain”, “encompass”, “comprise” and the like hereinafter are open terms which on the one hand indicate the presence of the stated elements or features, and on the other hand do not exclude the presence of further elements or features. The indefinite articles and the definite articles encompass both the plural and the singular, unless something different is unambiguously evident from the context.

The term “horizontal” as used in the present description is intended to describe an orientation substantially parallel to a first or main surface of a semiconductor substrate or body. Said surface can be for example the surface of the wafer or of a die or chip.

The term “vertical” as used in the present description is intended to describe an orientation arranged substantially perpendicular to the first surface, i.e. parallel to the direction of the normal to the first surface, of the semiconductor substrate or body.

If a value range with the indication of one limit value or two limit values is defined for a physical variable, then the prepositions “from” and “to” include the respective limit value. An indication of the type “from . . . to” is accordingly understood as “from at least . . . to at most”.

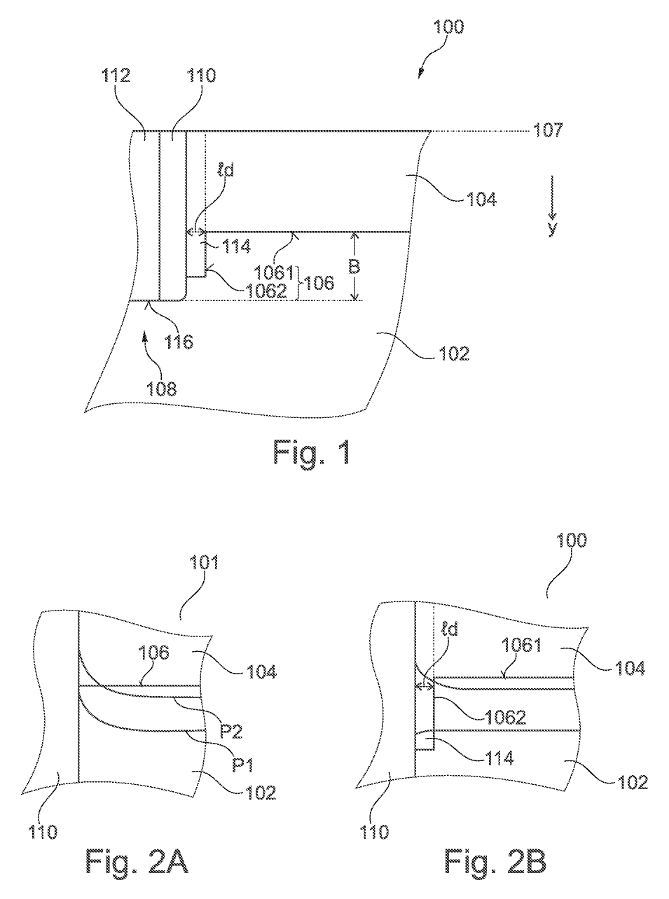

The schematic cross-sectional view in FIG. 1 illustrates one exemplary embodiment of a semiconductor device 100. The semiconductor device can be for example a discrete semiconductor device or else an integrated circuit (IC). In this regard, the semiconductor device comprises for example various circuit blocks, which can comprise analog and/or digital blocks and/or power transistors.

The semiconductor device 100 comprises a semiconductor substrate 102 of a first conductivity type. The first conductivity type can be a p-type or an n-type. The semiconductor substrate 102 can be based on various semiconductor materials, such as, for instance, silicon, silicon-on-insulator (SOI), silicon-on-sapphire (SOS), silicon-germanium, germanium, gallium arsenide, silicon carbide, gallium nitride or else further compound semiconductor materials.

The semiconductor device 100 comprises a semiconductor layer 104 of a second conductivity type on the semiconductor substrate 102. The second conductivity type can be a p-type or an n-type and is different than the first conductivity type. A first section 1061 of a pn junction 106 is formed between the semiconductor layer 104 and the semiconductor substrate 102.

A trench structure 108 extends through the semiconductor layer 104 into the semiconductor substrate 102, wherein the trench structure 108 comprises an insulation structure 110 and a contact structure 112. In this case, the trench structure 108 extends for example from a first surface 107 of the semiconductor layer 104 in a vertical direction y in the direction of the semiconductor substrate 102. Sidewalls of the trench structure can be oriented perpendicular to the first surface 107 or else at an angle that deviates from 90°, a so-called taper angle, with respect to the first surface 107. The sidewalls of the trench structure 108 can comprise for example planar sections, curved sections or else edges.

The insulation structure 110 can comprise one or a plurality of insulating materials arranged for example in the form of a layer stack. Examples of insulating materials of the insulation structure that may be mentioned are oxides such as SiO₂ as thermal oxide, oxides produced by means of vapor deposition (CVD, chemical vapor deposition), e.g. borophosphosilicate glass (BPSG), phosphosilicate glass (PSG), borosilicate glass (BSG), and nitrides, high- and low-k dielectrics or else any desired combination of these materials. The insulation structure can end at the first surface 107 or else extend into a wiring area formed above the first surface 107, where it can adjoin a further dielectric, for example.

The contact structure 112 can comprise one or a plurality of conductive materials arranged for example in the form of a layer stack. Examples of conductive materials of the contact structure 112 that may be mentioned are metals, metal silicides, conductive metal-containing compounds such as metal nitrides, alloys, highly doped semiconductors such as highly doped polycrystalline silicon or else any desired combination of these materials. The contact structure 112 can end at the first surface 107 or else extend into a wiring area formed above the first surface, where it can adjoin for example a further conductive structure such as, for instance, a contact plug or a conductor track or else a conductor area such as a contact pad.

The insulation structure 110 is formed between the semiconductor layer 104 and the contact structure 112 and also between the semiconductor substrate 102 and the contact structure 112. The contact structure 112 is electrically connected to the semiconductor substrate 102 at a bottom 116 of the trench structure 108. In order to produce an ohmic contact between the trench structure 108 and the semiconductor substrate 102, it is possible, for example depending on a dopant concentration of the semiconductor substrate 102, to arrange a contact mediating layer such as a highly doped semiconductor layer, for instance, at the bottom 108.

Exemplary dopant concentrations of the semiconductor substrate 102 can exceed 10¹⁸ cm⁻³, 5×10¹⁸ cm⁻³ or even 10¹⁹ cm⁻³. As a result, a parasitic bipolar transistor that forms with the semiconductor substrate 102 as a base and sections of the semiconductor layer 104 as the emitter and the collector, said sections being separated by the trench structure 108, can be impaired or even suppressed. A highly doped semiconductor substrate can likewise be used for a low-impedance electrical contact between the semiconductor substrate 102 and a conductive filling within the trench structure. Moreover, the semiconductor substrate 102 can have a low or moderate dopant concentration, e.g. dopant concentrations of less than 10¹⁶ cm⁻³, or less than 10¹⁵ cm⁻³, or even less than 10¹⁴ cm⁻³. This can contribute for example to an increase in the blocking capability of an electric breakdown with respect to the semiconductor substrate 102 by virtue of part of the low or moderate semiconductor substrate doping being used for taking up part of the reverse voltage. Moreover, the semiconductor substrate 102 can comprise a highly doped first semiconductor substrate area and a lightly or moderately doped second semiconductor substrate area on the first semiconductor substrate area in order thus to combine the advantages of a high doping of the semiconductor substrate 102 with the advantages of a low or moderate doping of the semiconductor substrate 102.

The semiconductor device 100 additionally comprises a first semiconductor region 114 of the second conductivity type, which adjoins the insulation structure 110 and extends along the trench structure 108 into a depth range B between the first section 1061 of the pn junction 106 and the bottom 116. Consequently, a second section 1062 of the pn junction 106 is formed between the first semiconductor region 114 and the semiconductor substrate 102. The first and second sections 1061, 1062 of the pn junction 106 merge into one another. In the overlap area between the semiconductor layer 104 and the first semiconductor region 114, the first semiconductor region is illustrated in a dashed manner in FIG. 1 and the subsequent figures.

The first semiconductor region 114 can bring about a reduction of the curvature of the electrical potential lines in the area of the pn junction 106 in the vicinity of the trench structure 108. This reduction makes it possible to decrease the electric field strengths and thus to increase a breakdown voltage Vbr of the pn junction 106. This advantageous effect of the first semiconductor region 114 is illustrated on the basis of simulation results shown in FIGS. 2A and 2B.

The schematic cross-sectional view in FIG. 2A illustrates a semiconductor device 101 that lacks the first semiconductor region 114. The semiconductor device 100 shown in FIG. 2B comprises the first semiconductor region 114. The electrical equipotential lines P1 and P2 shown in FIGS. 2A and 2B serve for a simplified schematic illustration of simulation results in the case of a corresponding reverse voltage of the semiconductor devices 101, 100. In the exemplary embodiment in FIG. 2B, the first semiconductor region 114 makes it possible to reduce the curvature of the electrical equipotential lines P1, P2, and thus to increase the voltage blocking strength of the pn junction 106.

In accordance with one exemplary embodiment, a lateral distance ld between the second section 1062 of the pn junction 106 and the insulation structure 110 is less than 2 μm. A variation of the lateral distance ld in the area mentioned leads to a variation of the background charge in the depleted state of the pn junction 106 and thus to a variation of the electric field distribution. The lateral distance ld can thus be optimized with regard to the least possible curvature of the electrical equipotential lines.

The first semiconductor region 114 is for example partly formed in an oppositely doped area of the semiconductor substrate 102. Thus, in the first semiconductor region 114, a concentration of electrically active dopants of the second conductivity type is greater than a concentration of electrically active dopants of the first conductivity type of the semiconductor substrate 102.

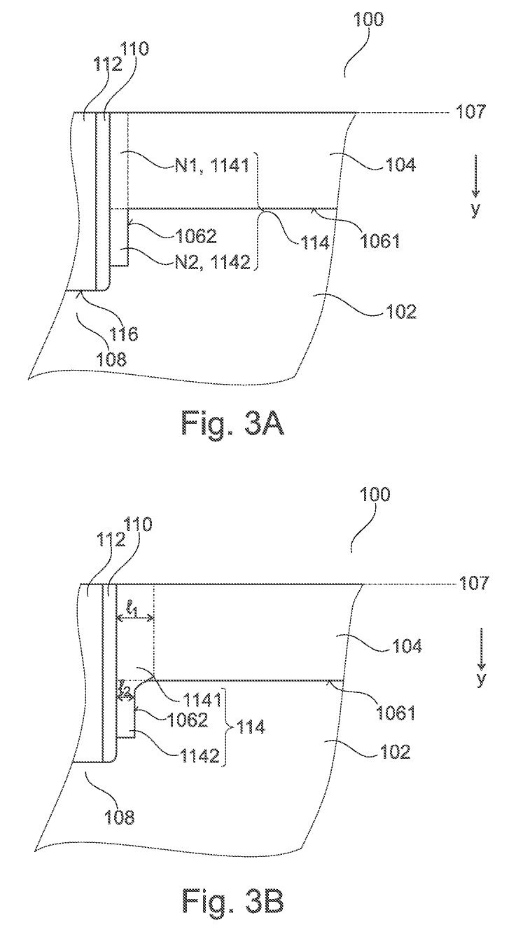

In accordance with one exemplary embodiment shown in FIG. 3A, the first semiconductor region 114 comprises a first area 1141 and a second area 1142 between the first area 1141 and the base 116.

A maximum dopant concentration N2 in the second area 1142 is less than a maximum dopant concentration N1 in the first area 1141. This exemplary embodiment makes it possible to optimize the first semiconductor region with regard to the function thereof at different locations in the semiconductor device 100.

By way of example, it is possible to optimize the maximum dopant concentration N2 in the second area 1142 with regard to the reduction of the electrical equipotential lines during off-state operation near the electrical breakdown of the semiconductor device 100 in order thus to obtain an increase in the breakdown voltage Vbr at the pn junction 106 and thus a further improvement of the voltage blocking behavior.

By way of example, it is possible to optimize the maximum dopant concentration N1 in the first area 1141 with regard to the suppression of an undesired MOS channel along a sidewall of the trench structure 108 between the semiconductor substrate 102 and a connection region at the first surface 107 or else with regard to a low-impedance electrical connection between a buried area at the junction with the semiconductor substrate 102 and a semiconductor connection region at the first surface 107.

In the case of the exemplary embodiment shown in FIG. 3B, a lateral dimension 11 of the first area 1141 is greater than a lateral dimension 12 of the second area 1142. In a similar manner to that explained in association with the exemplary embodiment in FIG. 3A, a different configuration of the lateral dimensions 11, 12 in the first and second areas 1141, 1142 can also contribute to the improvements described above.

The exemplary embodiments in FIG. 3A and FIG. 3B can be combined with one another in order to achieve a further improvement in the desired technical effect.

A transition between first and second area 1141, 1142 can take place for example at a vertical distance from the first surface 107 which is such that it is expedient with regard to a spatial separation of the first semiconductor region 114 into different functional areas. By way of example, the transition can lie at a depth or in the area of the depth of the first section 1061 of the pn junction 106. Moreover, it is possible to carry out an even finer subdivision of the first semiconductor region 114 into more than the two areas 1141, 1142 shown by way of example in FIGS. 3A and 3B, e.g. three, four, five or even more areas can be formed within the first semiconductor region 114. Said areas can differ with regard to their maximum dopant concentration and/or lateral dimensioning and/or some other structural parameter with a functional effect. By way of example, a lateral dopant profile or a dopant species can be taken into account as further parameters with a functional effect.

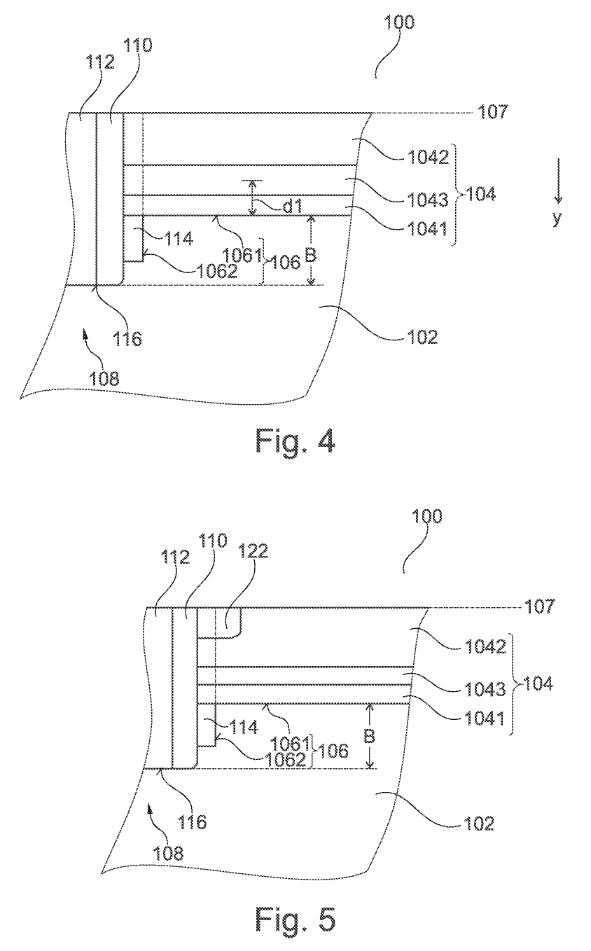

In accordance with the exemplary embodiment of the semiconductor device 100 as shown in FIG. 4, the semiconductor layer 104 comprises a third area 1043, which is more highly doped than first and second areas 1041, 1042 of the semiconductor layer 104 that adjoin the third area 1043 downward and upward.

One or a plurality or all of the areas 1041, 1042, 1043 can be, for example, deposited partial layers of the semiconductor layer 104. Said partial layers can be deposited for example by means of a suitable production method such as chemical vapor deposition (CVD), for instance. Likewise, one or a plurality of the areas 1041, 1042, 1043 can also be produced within one of the partial layers or else in the semiconductor substrate by the introduction of dopants, e.g. by ion implantation and/or indiffusion from a diffusion source.

In accordance with one exemplary embodiment, the first area 1041 is deposited and the third area 1043 is produced by ion implantation of dopants into the first area 1041. This is followed by a deposition of the second area 1042 on the first area 1041. Owing to the thermal budget during the subsequent processing of the semiconductor device 100, dopants of the third area diffuse upward and downward, such that the third area occupies an upper part of the deposited first area 1041 and a lower part of the deposited second area 1042. The first and second areas 1041, 1042 can differ from the third area for example with regard to the dopant profile. Moreover, one dopant species or a combination of a plurality of dopant species in the third area 1043 can differ from the first and/or second area 1041, 1042.

In accordance with one exemplary embodiment, a vertical distance between a maximum of a dopant concentration profile in the third area 1043 of the semiconductor layer 104 and the first section 1061 of the pn junction 106 lies in a range of from 1 μm to 60 μm, or else in a range of from 10 μm to 15 μm. In the schematic cross-sectional view in FIG. 4, for exemplary illustration, said distance is put into a vertical center of the third area 1043 of the semiconductor layer 104 and designated by dl. The definition of the parameter dl makes it possible to set a desired voltage blocking capability, i.e. an electrical breakdown voltage between the semiconductor layer 104 and the semiconductor substrate 102.

In accordance with one exemplary embodiment, the maximum dopant concentration of the third area 1043 lies between 5×10¹⁷ cm⁻³ and 1×10²¹ cm⁻³. A vertical dopant profile in the third area 1043 can correspond for example to a dopant profile that results from the thermal widening of one or more ion implantation profiles. In this regard, the third area 1043 can comprise for example one or more dopant species, e.g. phosphorous and/or arsenic in the case of an n-doped doping. If phosphorous and arsenic are combined within the third area 1043, then the arsenic dopants can contribute for example to a large maximum value of the doping in order to achieve high transverse conductivities within the third area 1043 or else in order to impair or to suppress a parasitic vertical pnp transistor into the semiconductor substrate 102. Likewise, the phosphorous dopants can contribute to a softer or flatter dopant profile at the junction with the semiconductor substrate 102 in order thus for example to contribute to increasing the breakdown voltage Vbr at the pn junction 106.

In accordance with the exemplary embodiment shown in FIG. 5, the semiconductor device 100 comprises a semiconductor connection region 122 of the second conductivity type, wherein a partial area of the first semiconductor region 114 extends along the trench structure 108 from the third area 1043 as far as the semiconductor connection region 122. This contributes to a reduction of the electrical resistance between the third area 1043 and an electrical contact structure at the first surface 107.

The semiconductor device 100 can be for example a semiconductor device having a breakdown voltage Vbr of the pn junction 106 in a range of from 80 V to 200 V. One exemplary field of application for such semiconductor devices is chips for the automotive industry. With the trend toward higher voltages on the on-board electrical system of a motor vehicle such as the V on-board electrical system, for instance, the power consumption of the device parts is also increasing and can obtain values in the region of 1 kW or more, for example. The embodiments described in this application can cope with these requirements by virtue of the fact that they make possible the technology voltage classes required for such chips. The chips can be realized for example using mixed semiconductor technologies, which can comprise bipolar circuit elements for realizing analog circuit blocks, CMOS (complementary metal oxide semiconductor) circuit elements for realizing digital circuit blocks and power transistors for realizing switches such as low-side switches, high-side switches and bridge configurations. Such semiconductor technologies are also known as BCD (Bipolar CMOS DMOS) technology or SPT (Smart Power Technology).

The trench structure 108 described in the exemplary embodiments serves for example for the electrical insulation of circuit elements in different sections of the semiconductor layer 104, which adjoin the trench structure 108 from opposite sides, for instance. The circuit elements can be arbitrary circuit elements in a mixed technology, e.g. field effect transistors of different voltage classes, diodes, bipolar transistors of different voltage classes, CMOS circuit elements, resistors, capacitances, power transistors.

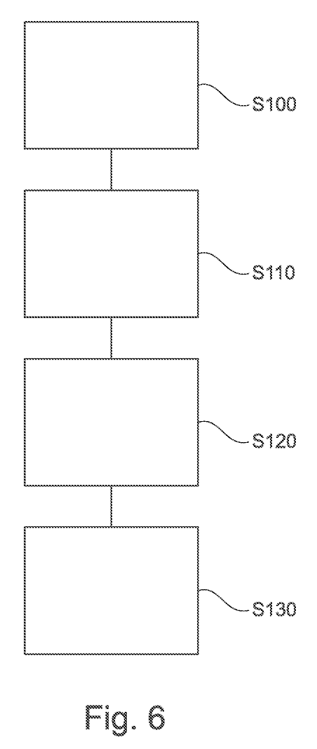

The flow diagram shown in FIG. 6 serves for elucidating one exemplary embodiment of a method for producing a semiconductor device.

The method is illustrated as a juxtaposition of method steps, wherein further steps for producing the semiconductor device can be carried out before, between and after the method steps illustrated. Moreover, the method steps illustrated can consist of one or more process steps.

Method step S100 comprises forming a semiconductor layer of a second conductivity type on a semiconductor substrate of a first conductivity type. The indications concerning the semiconductor layer and the semiconductor substrate given in association with the exemplary embodiments above are analogously applicable to the method step. By way of example, forming the semiconductor layer comprises at least one-layer deposition process, wherein the semiconductor layer can be doped in situ, by ion implantation, by indiffusion of dopants or else by a combination of these methods.

Method step S110 comprises forming a trench extending through the semiconductor layer into the semiconductor substrate. Forming the trench can be carried out for example by means of a lithographically patterned etching mask, e.g. a resist mask or a hard mask. The etching can be carried out for example anisotropically by means of a suitable etching method such as a dry etching method, e.g. reactive ion etching (RIE).

Method step S120 comprises forming a first semiconductor region of the second conductivity type at a sidewall of the trench by introducing a dopant through the sidewall into the semiconductor substrate and into the semiconductor layer. The dopant can be implemented for example by means of ion implantation and/or indiffusion from a dopant source. Moreover, it is possible to introduce different dopants for forming the first semiconductor region in a plurality of steps. The indications concerning the first semiconductor region given in association with the exemplary embodiments above are analogously applicable to the method step.

Method step S130 comprises forming an insulation structure and a contact structure in the trench, wherein the insulation structure is formed between the semiconductor layer and the contact structure and also between the semiconductor substrate and the contact structure, and the contact structure is electrically connected to the semiconductor substrate at a bottom of the trench. The indications concerning the insulation structure and concerning the contact structure given in association with the exemplary embodiments above are analogously applicable to the method step.

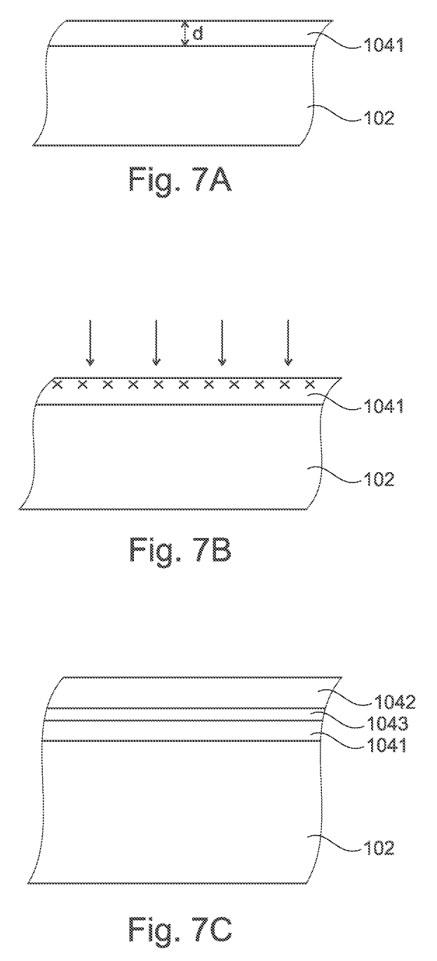

In accordance with one exemplary embodiment shown in the schematic cross-sectional views in FIGS. 7A to 7C, forming the semiconductor layer 104 comprises forming a first area 1041 of the semiconductor layer 104 on the semiconductor substrate 102, cf. FIG. 7A. Forming the first area can be carried out for example by means of a suitable layer deposition process such as a CVD process, for instance. In accordance with one exemplary embodiment, the first area 1041 is formed with a thickness in a range of from 1 μm to 50 μm, or else in a range of from 10 μm to 15 μm. Forming the first area 1041 can comprise for example doping the first area 1041 with dopants of the second conductivity type in a range of from 10¹⁵ cm⁻³ to 5×10¹⁷ cm⁻³. The doping can be carried out for example in situ or else, alternatively or supplementarily, by means of ion implantation or diffusion from a dopant source. In this case, a dopant concentration profile of the first area can be constant or approximately constant or else fall at least partly in a direction toward the semiconductor substrate 102.

Referring to the cross-sectional view shown in FIG. 7B, dopants of the second conductivity type are introduced into the first area 1041, e.g. by ion implantation and/or indiffusion. The dopants introduced are illustrated by the symbol “x” in the schematic view in FIG. 7B and serve for forming a third area.

Referring to the schematic cross-sectional view in FIG. 7C, a second area 1042 is formed on the first area 1041, e.g. by means of a layer deposition process. The dopants of the second conductivity type which were introduced into the first area 1041 in the process step illustrated in FIG. 7B diffuse downward and upward into the first and second areas 1041, 1042 as a result of a thermal budget during the processing of the semiconductor device and form a third area 1043 arranged between the first and second areas 1041, 1042, said third area having a maximum dopant concentration greater than that of the first area 1041 and the second area 1042. The indications concerning the semiconductor layer 104 and the areas 1041, 1042 and 1043 given in association with the exemplary embodiments above are analogously applicable to the method steps described.

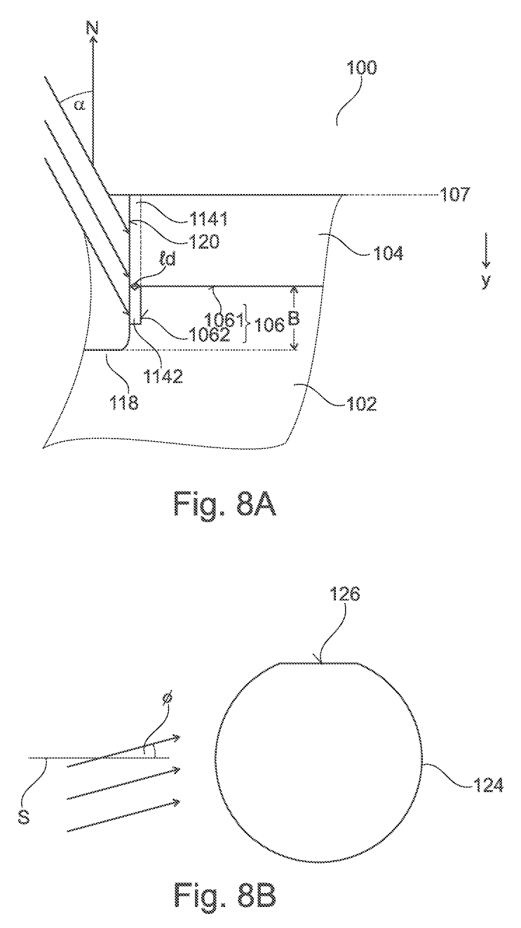

In accordance with one exemplary embodiment, the dopants of the first semiconductor region 114 are introduced by ion implantation with a dose in a range of from 1×10¹³ cm⁻² to 1×10¹⁶ cm⁻². By way of example, the first semiconductor region 114 can be formed by a plurality of ion implantation steps. As is illustrated in the schematic views in FIGS. 8A and 8B, the plurality of ion implantation steps can differ in one or in a plurality of the parameters: angle of inclination a with respect to a surface normal N of the semiconductor substrate 102, angle of rotation (twist) Φ with respect to a perpendicular S to the surface normal N, ion implantation dose and ion implantation energy. The view in FIG. 8B illustrates an exemplary plan view of a wafer 124 in which the semiconductor device 100 is produced. The angle of rotation Φ can be dimensioned for example relative to a wafer flat 126. Moreover, the wafer 124 can comprise other means for identifying the orientation, e.g. a notch.

By varying the angle of inclination α, it is possible for example to implant different doses into different depth areas of the first semiconductor region 114 on account of shading effects through the implantation mask. By way of example, by this means the exemplary embodiment described in FIG. 3A can be fabricated by an implantation dose of the dopants for the first area 1141 being chosen to be greater than an implantation dose of the dopants for the second area 1142. By way of example, by means of a first ion implantation step at a first angle of inclination α1, a first dose is implanted both into the first area 1141 and into the second area 1042 through a sidewall 120 of a trench 118, and, by means of a second ion implantation step at a second angle of inclination α2, which is less than or greater than the first angle of inclination α1, a second dose is implanted only into the first area 1141 through the sidewall 120 of the trench 118.

By varying the angle of rotation Φ by 180°, it is possible to implant dopants for example through opposite sidewalls of the trenches. Since the trenches and trench structures 108 produced therefrom can have different shapes in a plan view as shown in FIG. 8B, e.g. can be configured in a strip-shaped or latticelike fashion, by repeating an ion implantation step at a different angle of rotation, it is possible to implant a desired ion implantation dose through differently oriented trench sidewalls.

Although specific embodiments have been illustrated and described herein, those skilled in the art will recognize that the specific embodiments shown and described can be replaced by a multiplicity of alternative and/or equivalent configurations, without departing from the scope of protection of the invention. The application is intended to cover any adaptations or variations of the specific embodiments discussed herein. Therefore, the invention is restricted only by the claims and the equivalents thereof.

What is claimed is:

1. A semiconductor device, comprising:
a semiconductor substrate of a first conductivity type;
a semiconductor layer of a second conductivity type on the semiconductor substrate, such that a first section of a pn junction is formed between the semiconductor layer and the semiconductor substrate;
a trench structure extending through the semiconductor layer into the semiconductor substrate, the trench structure comprising an insulation structure and a contact structure, the insulation structure being formed between the semiconductor layer and the contact structure and also between the semiconductor substrate and the contact structure, the contact structure being electrically connected to the semiconductor substrate at a bottom of the trench structure; and
a first semiconductor region of the second conductivity type, which adjoins the insulation structure and extends along the trench structure into a depth range between the first section of the pn junction and the bottom, such that a second section of the pn junction is formed between the first semiconductor region and the semiconductor substrate.

2. The semiconductor device of claim 1, wherein a lateral distance between the second section of the pn junction and the insulation structure is less than 2 μm.

3. The semiconductor device of claim 1, wherein the first semiconductor region is formed in an oppositely doped area of the semiconductor substrate.

4. The semiconductor device of claim 1, wherein the first semiconductor region comprises a first area and a second area between the first area and the bottom, and wherein a maximum dopant concentration in the second area is less than in the first area and/or the first area has a larger dimensioning along a lateral direction than the second area.

5. The semiconductor device of claim 1, wherein the semiconductor layer comprises a third area, which is more highly doped than first and second areas of the semiconductor layer that adjoin the third area downward and upward.

6. The semiconductor device of claim 5, further comprising:
a semiconductor connection region of the second conductivity type,
wherein a partial area of the first semiconductor region extends along the trench structure from the third area of the semiconductor layer as far as the semiconductor connection region.

7. The semiconductor device of claim 5, wherein a vertical distance between a maximum of a dopant concentration profile in the third area of the semiconductor layer and the first section of the pn junction is in a range of 1 μm to 50 μm.

8. The semiconductor device of claim 5, wherein a maximum dopant concentration of the third area of the semiconductor layer is in a range of 5×10¹⁷ cm⁻³ and 1×10²¹ cm⁻³.

9. The semiconductor device of claim 1, wherein a plurality of semiconductor circuit elements is formed in different sections of the semiconductor layer, wherein the trench structure is configured to electrically insulate adjacent sections of the semiconductor layer, and wherein the adjacent sections adjoin the trench structure from opposite sides.

10. A method for producing a semiconductor device, the method comprising:
forming a semiconductor layer of a second conductivity type on a semiconductor substrate of a first conductivity type;
forming a trench extending through the semiconductor layer into the semiconductor substrate;
forming a first semiconductor region of the second conductivity type at a sidewall of the trench by introducing a dopant through the sidewall into the semiconductor substrate and into the semiconductor layer; and
forming an insulation structure and a contact structure in the trench such that the insulation structure is formed between the semiconductor layer and the contact structure and also between the semiconductor substrate and the contact structure, and the contact structure is electrically connected to the semiconductor substrate at a bottom of the trench.

11. The method of claim 10, wherein forming the semiconductor layer comprises:
forming a first area of the semiconductor layer on the semiconductor substrate;
introducing dopants of the second conductivity type into the first area; and
forming a second area on the first area, wherein dopants of the second conductivity type form a buried area, which is more highly doped than the first and second areas of the semiconductor layer that adjoin the buried area downward and upward.

12. The method of claim 11, wherein a thickness of the first area is in a range of 1 μm to 50 μm.

13. The method of claim 11, wherein forming the first area comprises doping the first area with dopants of the second conductivity type in a range of from 10¹⁵ cm⁻³ to 1×10¹⁷ cm⁻³.

14. The method of claim 11, wherein the dopant of the first semiconductor region is implanted through the sidewall into the semiconductor substrate and into the semiconductor layer.

15. The method of claim 14, wherein an implantation dose of the dopant of the first semiconductor region is set in a range of 1×10¹³ cm⁻² to 1×10¹⁶ cm⁻².

16. The method of claim 14, wherein the first semiconductor region is formed by a plurality of ion implantation steps, and wherein the plurality of ion implantation steps differ in one or more of the following parameters: angle of inclination with respect to a surface normal of the semiconductor substrate; angle of rotation with respect to a perpendicular of the surface normal; ion implantation dose; and ion implantation energy.

17. The method of claim 16, wherein the first semiconductor region comprises a first area and a second area between the first area and the bottom, and wherein an implantation dose of the dopants for the first area is greater than an implantation dose of the dopants for the second area.

18. The method of claim 10, wherein the first semiconductor region oppositely dopes an area of the semiconductor substrate.
